(19) United States
(12) Patent Application Publication
(10) Pub. No.: US 2014/0159490 A1
(43) Pub. Date: Jun. 12, 2014

(54) POWER CONVERTER, ELECTRONIC DEVICE AND METHOD FOR DETECTING OUTPUT POWER OF POWER CONVERTER

(71) Applicant: PEGATRON CORPORATION, Taipei City (TW)

(72) Inventors: PO-YUAN CHENG, Taipei City (TW); CHUN-WEI KO, Taipei City (TW)

(73) Assignee: PEGATRON CORPORATION, Taipei City (TW)

(21) Appl. No.: 14/080,081

(22) Filed: Nov. 14, 2013

(30) Foreign Application Priority Data
Dec. 7, 2012 (TW) 101146161

(51) Int. Cl. G01R 21/00; H02M 1/00

(52) U.S. Cl. CPC G01R 21/00; H02M 1/00
USPC 307/52; 323/234; 324/76.11

(57) ABSTRACT

A method for detecting output power of a power converter is applied for detecting power outputted from the power converter as an electronic device is electrically connected with the power converter. The method comprises the following steps: First, it is to control a battery of the electronic device to supplies power to the electronic device and disconnecting a power supply path of supplying the power from the power converter to the electronic device. After disconnecting the power supply path, the impedance of the voltage dividing circuit of the power converter is regulated to vary the power supply voltage outputted to the electronic device. And then, the varied power supply voltage is detected and the power outputted form the power converter will be recognized according to the power supply voltage.

### CROSS-REFERENCE TO RELATED APPLICATIONS

This Non-provisional application claims priority under 35 U.S.C. §119(a) on Patent Application No(s). 101146161 filed in Taiwan, R.O.C. on Dec. 7, 2012, the entire contents of which are hereby incorporated by reference.

### BACKGROUND OF THE INVENTION

1. Field of the Invention

This invention relates to a method for detecting an output power of a power converter and, more particularly, to a method for detecting power outputted from a power converter having only two pins.

2. Description of the Related Art

The commercial power converters can be divided into two types according to the number of pins of its joint. One is the traditional power converter having only two pins, and the other one is a power converter having an additional pin for recognition thus to have three pins therein. In the modern power converter, the additional pin can be utilized on the detection of power and it also can be distinguished into two different detecting methods as described in the following according to the difference of the implements.

The first one is a resistance voltage dividing type, and when the joint of the power converter is inserted into the socket of the electronic device, a voltage level will be obtained after an impedance disposed inside the power converter is connected with a voltage dividing circuit, which is located at a circuit board of the electronic device, in series/parallel. Because the power converters having different output power have different value of the impedance disposed therein, voltage dividing level obtained after series/parallel connection will be different. Thus, a control unit of the electronic device can recognize the type of the power converter by detecting the difference of the voltage level.

The other one is loading the information of the output power of the power converter in the erasable programmable read only memory (EPROM) of the power converter. The power converters having different output power have different information therein Therefore, when the joint having the recognizable pin is inserted into the socket of the electronic devices, the control unit can read the information stored in the ROM to distinguish a power value outputted from the power converter.

The traditional joint of the power converter having only two pins cannot detect and determine the output power of the power converter which is different with the power converter having three pins. However, the power converter having three pins are very expensive even if they can apply on detects and determines the output power of the power converter. Thus, a new method for detecting the output power of traditional power converter is necessary due to the cost consideration.

### BRIEF SUMMARY OF THE INVENTION

A main purpose of the present invention is to provide a method for detecting power outputted from a power converter having only two pins.

A further purpose of the present invention is to provide a power converter to execute the abovementioned detecting method.

A still further purpose of the present invention is to provide an electronic device to execute the abovementioned method and detect the output power of the power converter.

In order to achieve the abovementioned purposes, the method for detecting the output power of the power converter disclosed in the present invention is used for detecting the power outputted from the power converter when the electronic device is electrically connected with the power converter. The power converter comprises a power regulation module and a voltage dividing circuit. The power regulation module is used for regulating a voltage inputted through the external power to generate a regulating voltage, and the voltage dividing circuit is used for generating a power supply voltage according to the regulating voltage, and in which the voltage dividing circuit comprises an impedance regulating apparatus for regulating an impedance of the voltage dividing circuit to allow the power supply voltage being varied according to the variation of the impedance. The method for detecting the output power of the power converter disclosed in the present invention comprises the following steps: a step of controlling a battery to supply power to the electronic device and disconnect a power supply path of supplying the power from the power converter to the electronic device is performed first. After the power supply path is disconnected, the impedance is regulated by the impedance regulating apparatus to varied the power supply voltage. The varied power supply voltage is detected and a power value is recognized according to the varied power supply voltage.

The power converter disclosed in the present invention is used for electrically connecting an external power with an electronic device to allow the external power supply power to the electronic device via the power converter. The electronic device comprises a power supply switch and a control unit, the power supply switch is used for connecting or disconnecting a power supply path of supplying the power from the power converter to the electronic device, and the control unit is used for controlling the power supply switch and detecting a power supply voltage outputted from the power converter. The power converter of the present invention comprises a power regulation module, a voltage dividing circuit and a converter control unit. The power regulation module is used for regulating a voltage inputted through the external power to generate a regulating voltage. The voltage dividing circuit is electrically connected with the power regulation module for generating the power supply voltage according to the regulating voltage and comprises an impedance regulating apparatus for regulating an impedance of the voltage dividing circuit to allow the power supply voltage being varied according to the variation of the impedance. The converter control unit is used for controlling the impedance regulating apparatus to vary the impedance as the power supply path is disconnected.

The electronic device of the present invention is used for detecting power outputted from the power converter as the electronic device is electrically connected with the power converter. The power converter comprises a power regulation module and a voltage dividing circuit, and in which the power regulation module is used for regulating a voltage inputted from an external power to generate a regulating voltage and the voltage dividing circuit is used for generating a power supply voltage according to the regulating voltage to supply power to the electronic device through the power supply voltage. Moreover, the voltage dividing circuit comprises an impedance regulating apparatus for regulating an impedance of the voltage dividing circuit to vary the power supply voltage according to the variation of the impedance. The electronic device of the present invention comprises a battery, a power supply switch and a control unit. The power supply switch is used for connecting or disconnecting a power supply path of supplying the power from the power converter to the electronic device, and the control unit is used for detecting the power supply voltage, controlling the battery to supply the power to the electronic device and controlling the power supply switch to disconnect the power supply path as the battery supplies the power to the electronic device.

### BRIEF DESCRIPTION OF THE DRAWINGS

FIG. 1 is a schematic diagram showing a power converter and an electronic device according to the present invention; and

FIG. 2 is a flow chart showing a method for detecting output power of the power converter according to the present invention.

### DETAILED DESCRIPTION OF THE INVENTION

In the following embodiments and figures, the features and advantages of the present invention will be described in sufficient detail and any person skilled in the art can easily understand the object and advantages of the present invention.

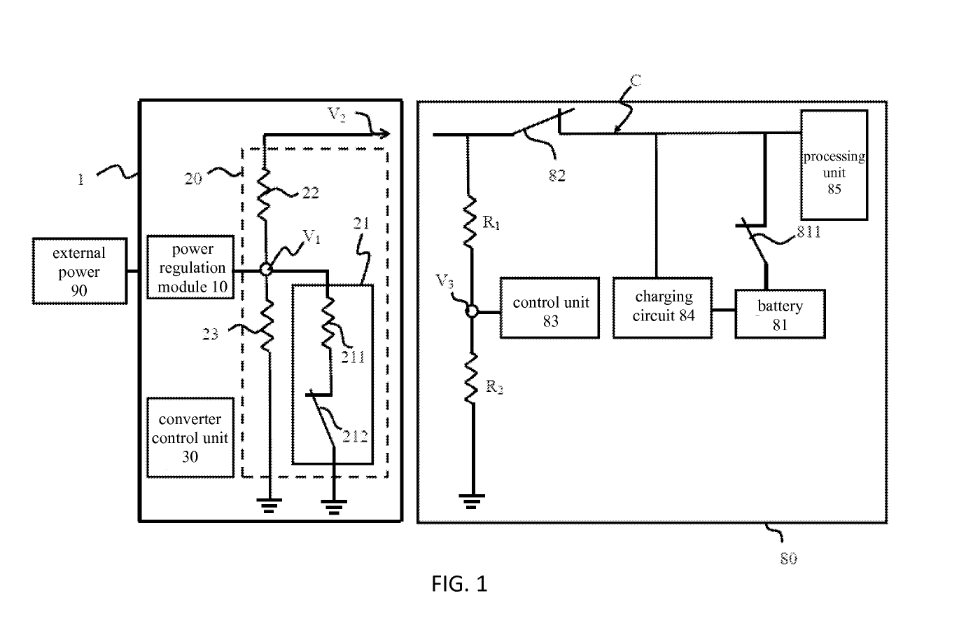

Please refer to FIG. 1. FIG. 1 is a schematic diagram showing a power converter and an electronic device according to the present invention.

As shown in FIG. 1, the electronic device 80 of the present invention is capable of being electrically connected with an external power 90 through a power converter 1. When the power converter 1 is electrically connected with the external power 90 and the electronic device at the same time, the power converter 1 can allow the external power 90 generate an input voltage/current, which is delivered to the electronic device 80 after regulating to provide a power supply voltage V₂ to the electronic device 80, and the regulated current is delivered to the electronic device 80 through a power supply path C to supply power to the electronic device 80. In an embodiment of the present invention, the electronic device 80 is a notebook, but it is not limited thereto.

In an embodiment of the present invention, the electronic device 80 comprises a battery 81, a power supply switch 82, a control unit 83, a first dropping resistance R₁, a second dropping resistance R₂, a charging circuit 84 and a processing unit 85.

When the external power 90 stops supplying power or the power converter 1 cannot supply the power to the battery 81 through a power supply path C, the battery 81 is used for supplying the power to the electronic 80 by the connection of a battery charging switch 811.

The power supply switch 82 is used for connecting or disconnecting the power supply path C of supplying the power from the power converter 1 to the electronic device 80.

The control unit 83 is capable of detecting the electric quantity of the battery 81 and the power supply voltage V₂, and used for controlling the battery charging switch 811 to be connected or disconnected. When the battery charging switch 811 is connected and the battery supplies the power to the electronic device 80, the control unit 83 can control the power supply switch 82 to disconnect the power supply path C. In the embodiment of the present invention, the control unit 83 is an embedded controller (EC), but the present invention is not limited thereto. The control unit 83 also can be a keyboard controller (KBC) or a micro processor.

The first dropping resistance R₁ and the second dropping resistance R₂ are used for dropping the power supply voltage V₂ to generate a dropping voltage V₃ and allow the control unit 83 detect and determine the value of the power supply voltage V₂ by detecting the value of the dropping voltage V₃.

In an embodiment of the present invention, the power converter 1 of the present invention comprises a power regulation module 10, a voltage dividing circuit 20 and a converter control unit 30.

The power regulation module 10 is used for filtering the voltage/current inputted from the external power 90 and dropping its voltage to generate a regulating voltage V₁.

The voltage dividing circuit 20 is electrically connected with the power regulation module 10. The voltage dividing circuit 20 comprises impedance regulating apparatus 21, a first resistance 22 and a second resistance 23, and in which the second resistance 23 is connected with the first resistance 22 in series and then grounded. The regulating voltage V1 generated from the power regulation module 10 is inputted between the first resistance 22 and the second resistance 23. In an embodiment of the present invention, the impedance regulating apparatus 21 is connected with the second resistance 23 in parallel and comprises a third resistance 211 and a switch 212. The third resistance 211 is connected with the switch 212 in series and then grounded. Furthermore, the power converters having different output power have different values of the third resistance 211 disposed therein. When the switch is connected, the third resistance 211 is connected with the second resistance 23 in parallel. At that time, the impedance of the voltage dividing circuit 20 can be the sum of the resistance obtained as the third resistance 211 is connected in parallel and then connected with the first resistance 22 in series. When the switch 212 is disconnected, the third resistance 211 and the second resistance 23 are not connected in parallel. At that time, the impedance of the voltage dividing circuit 20 can be the sum of the resistance obtained as the second resistance 23 is connected with the first resistance 22 in series. In an embodiment of the present invention, the switch is a relay, but the present invention is not limited thereto. The switch 212 also can be a metal-oxide-semiconductor field-effect transistor (MOSFET) or a bipolar junction transistor (BJT) or other electric control switches with any forms.

The converter control unit 30 is used for controlling the connection of the switch 212 when the power supply path is disconnected so as to vary the impedance of the voltage dividing circuit 20.

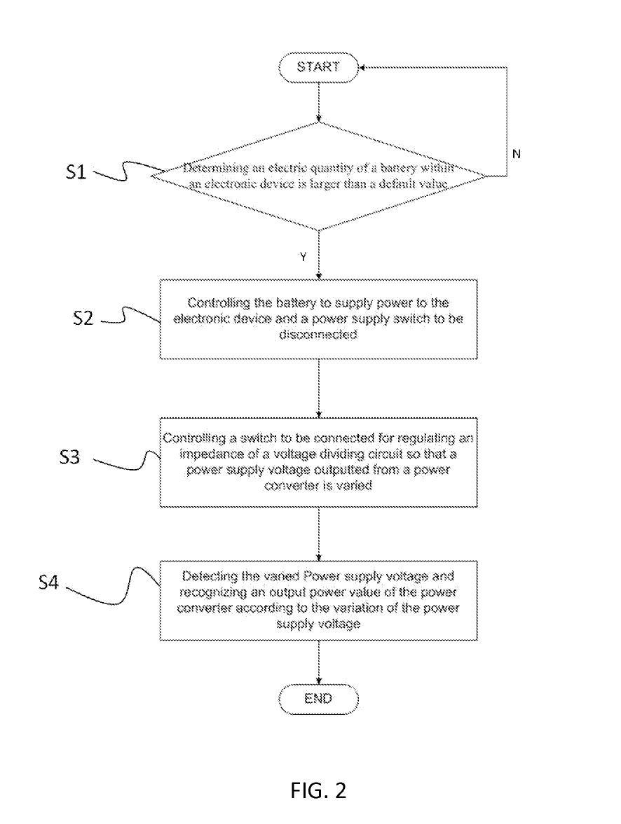

Please eventually refer to FIG. 2 together with FIG. 1, and in which FIG. 2 is a flow chart showing a method for detecting output power of the power converter according to the present invention.

As shown in FIG. 2, it shows the steps of the method for detecting output power of the power converter according to the present invention. In order to describe the detecting method of the present invention in details, each step of FIG. 2 will be illustrated in the following by utilizing the power converter 1 and the electronic device 80 shown in FIG. 1. It needs to be noted that although the power converter 1 and the electronic device 80 are used as an embodiment to illustrate the method for detecting the output power of the power converter in the present invention, the method of the present invention is not limited to be used in the abovementioned power converter 1 and the electronic device 80.

First, step S1 is performed to determine whether the electric quantity of the battery of the electronic device is larger than a default value.

In an embodiment of the present invention, a prerequisite of the detecting method disclosed in the present invention is to disconnect the power supply path C so that when the converter control unit 30 detects that the power converter 1 does not supply the power to the electronic device 80 (i.e. no load status), it can control the switch 212 to be connected or disconnected. Therefore, there is very short time to charge the electronic device 80 by the battery 81. Thus, the first step of the method for detecting the output power of the power converter as disclosed in the present invention is to determine whether the electric quantity of the battery 81 of the electronic device 80 is sufficient. For example, when the default value is set up at 50% of saturated electric quantity of the battery 81 and once the electric quantity of the battery 81 is lower than the default value, the following determining step will be postponed. At that time, the external power 90 supplies the power to the electronic device 80 first and charges the battery 81 at the same time. When the electric quantity of the battery 81 is charged to be larger than the default value by the external power 90, the following determining step is executed.

Step S2 is performed to control the battery to supply the power to the electronic device and control the power supply switch to be disconnected.

When the electric quantity of the battery 81 is larger than the default, it means the electric quantity of the battery 81 is sufficient. Thus, the control unit 83 will control the battery charging switch 811 to be connected to allow the battery 81 supplies the power to the electronic device 80 and then control the power supply switch 82 to be disconnected for disconnecting the power supply path C.

Step S3 is performed to control the switch to be connected for regulating the impedance of the voltage dividing circuit so as to vary the power supply voltage outputted from the power converter.

As shown in FIG. 1, once the power supply switch 82 is disconnected and the processing unit 85 cannot load the current, which is generated by the power converter 1, through the power supply path C, the output current of the power converter 1 will become very weak so that the converter control unit 30 can detect the variation of the output current and control the switch 212 to be connected after the power supply path is disconnected. When the switch 212 is connected, the impedance of the whole voltage dividing circuit 20 will varied due to the formation of the parallel connection between the third resistance 211, which is not connected with the second resistance 23 in parallel before the switch is connected, and the second resistance 23.

For example, it supposes that each the resistances of the first resistance 22, the second resistance 23 and the third resistance 211 is 5Ω, and the impedance of the voltage dividing circuit 20 is approximately equal to 5+5=10Ω when the switch 212 is not connected. That is, the impedance is equal to the sum of the resistance formed when the second resistance 23 is connected with the first resistance 22 in series. And when the switch 212 is connected, the impedance of the voltage dividing circuit 20 is approximately equal to (5/2)+5=7.5Ω That is, the impedance is equal to the sum of the resistance formed when the third resistance 211 is connected with the second resistance 23 in parallel and then connected with the first resistance 22 in series.

The power supply voltage V₂ generated from the voltage dividing circuit 20 will varies once the impedance of the voltage dividing circuit 20 varies. For example, it supposes that the regulating voltage V₁ regulated by the power regulation module 10 is 9 V, and the power supply voltage V₂ regulated by the voltage dividing circuit 20 is approximately equal to 9*(5+5)/5=18 V when the switch 212 is not connected. When the switch 212 is connected, the third resistance 211 is connected with the second resistance 23 in parallel so that the power supply voltage V₂ generated from the regulating voltage V₁, which is regulated by the voltage dividing circuit 20, is varied to 9*(5+2.5)/2.5=27 V.

Step S4 is finally performed to detect the varied power supply voltage and recognize a power value outputted from the power converter according to the varied power supply voltage.

According to the abovementioned, when the switch 212 is connected, he power supply voltage V₂ inputted from the power converter 1 to the electronic device 80 will vary. As shown in FIG. 2, the dropping voltage V₃ generated from the first dropping resistance R₁ and the second dropping resistance R₂ will vary as the power supply voltage V₂ varies. For example, it supposes that the first dropping resistance R₁ and the second dropping resistance R₂ are 16Ω and 2Ω,respectively. When the switch 212 is not connected, the power supply voltage V₂ is 18V and the generated dropping voltage V₃ is approximately equal to 18*2/(16+2)=2V. When the switch 212 is connected, the power supply voltage V₂ is 27V and the generated dropping voltage V₃ is varied into 27*2/(16+2)=3V.

Because the values of the third resistances 211 disposed in the power converters having different output powers are different, the different power converters 1 will output different power supply voltages V₂ after the switch 212 is connected. At the same time, the values of the dropping voltage V3 detected by the control unit 83 are also different. Thus, the electronic device 80 can recognize power values outputted from different power converters 1 according to the difference of the varied power supply voltage V₂ (or the dropping voltage V₃). In an embodiment, the information of the value of the varied power supply voltage V₂ with respect to the power value outputted from the power converter 1 (such as V2 is 27V and the corresponding power value is 65 W, or V₂ is 21 V and the corresponding power value is 90 W) can be written into a erasable programmable read only memory (EPROM). Thus, once the control unit 83 detects the value of the varied power supply voltage V₂, the corresponding power value can be found according to the detected value of the voltage.

For example, it supposes that the value of the third resistance 211 disposed in the power converter 1, which has an output power value of 65 W, is 5Ω (other resistances is the same as above supposed). Thus, the dropping voltage V₃ detected by the control unit 83 is approximately equal to 3V (i.e. the power supply voltage V₂ is 27V) when the switch is connected. Then, the control unit 83 can utilize the information stored in the memory to find the corresponding power value. It further supposes that the value of the third resistance 211, which is disposed in the power converter 1 with the output power value of 90 W, is 15Ω. After the switch 212 is connected, then power supply voltage V2 outputted from the power converter 1 is approximately equal to 9*{[5*15/(5+15)]+5}*[(5+15)/5*15]=21 and the dropping voltage V3 is approximately equal to 21*2/(16+2)=2.333V. Once the value of the dropping voltage V3 detected by the control unit 83 is 2.333V, the corresponding power value (W) outputted from the power converter 1 can be figured out.

After executing the steps S2 to S4, the electronic device 80 will make the battery charging switch 811 being disconnected, and the power supply switch 82 will be connected again to return to be supplied the power from the external power 90.

It needs to be noted that the method for detecting the output power of the power converter is not limited to the order of the above steps, and the order of the above steps can be varied as long as the purpose of the present invention can be achieved.

According to abovementioned, the method for detecting the output power of the power converter disclosed in the present invention can be performed to vary the output power supply voltage of the power converter by varying the impedance therein under a specific condition and recognize the power outputted from the power converter by detecting the varied power supply voltage. By utilizing the abovementioned detecting method, the power converter does not need the additional pin (i.e. only two pins) so that the manufacturing cost of the power converter can be reduced and the disadvantages of the prior art can be effectively improved.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A power converter for electrically connecting with an external power and an electronic device, wherein the external power supplies power to the electronic device via the power converter and the electronic device comprises a power supply switch for connecting or disconnecting a power supply path of supplying the power from the power converter to the electronic device and a control unit for controlling the power supply switch and detecting a power supply voltage outputted from the power converter, the power converter comprising:
a power regulation module for regulating a voltage inputted through the external power to generate a regulating voltage;
a voltage dividing circuit electrically connected with the power regulation module for generating the power supply voltage according to the regulating voltage, wherein the voltage dividing circuit comprises an impedance regulating apparatus for regulating an impedance of the voltage dividing circuit, and the power supply voltage is varied according to the variation of the impedance; and
a converter control unit for controlling the impedance regulating apparatus to vary the impedance as the power supply path is disconnected,
wherein when the impedance regulating apparatus regulates the impedance after the power supply path is disconnected, the control unit recognizes a power value outputted from the power converter by detecting the power supply voltage.

2. The power converter according to claim 1, wherein the voltage dividing circuit comprises a first resistance and a second resistance, the second resistance is connected with the first resistance in series and then grounded, the regulating voltage is inputted between the first resistance and the second resistance, and the impedance regulating apparatus is connected with the second resistance in parallel.

3. The power converter according to claim 2, wherein the impedance regulating apparatus comprises a third resistance and a switch, the third resistance is connected with the switch in series and then grounded; and the third resistance is connected with the second resistance in parallel when the switch is connected or not connected with the second resistance in parallel when the switch is disconnected for varying the impedance of the voltage dividing circuit by connecting or disconnecting the switch.

4. The power converter according to claim 3, wherein the switch is a relay, a metal-oxide-semiconductor field-effect transistor or a bipolar junction transistor.

5. An electronic device for detecting a power value outputted from a power converter as the electronic device is electrically connected with the power converter, and the power converter comprising a power regulation module for regulating a voltage inputted from an external power to generate a regulating voltage and a voltage dividing circuit for generating a power supply voltage according to the regulating voltage to supply power to the electronic device through the power supply voltage, wherein the voltage dividing circuit comprises an impedance regulating apparatus for regulating an impedance of the voltage dividing circuit to vary the power supply voltage according to the variation of the impedance, the electronic device comprising:
a battery;
a power supply switch for connecting or disconnecting a power supply path of supplying the power from the power converter to the electronic device; and
a control unit for detecting the power supply voltage, controlling the battery to supply the power to the electronic device and controlling the power supply switch to disconnect the power supply path as the battery supplies the power to the electronic device,
wherein when the impedance regulating apparatus regulates the impedance after the power supply path is disconnected, the control unit recognizes the power value outputted from the power converter by detecting the power supply voltage.

6. The electronic device according to claim 5, wherein the control unit is further used for detecting the electric quantity of the battery and determining whether the electric quantity of the battery conforms to a default value.

7. The electronic device according to claim 5, wherein the control unit is a keyboard controller (KBC), an embedded controller (EC) or a micro processor.

8. A method for detecting output power of a power converter for detecting a power value outputted from the power converter as an electronic device is electrically connected with the power converter, wherein the power converter comprises a power regulation module fro regulating a voltage inputted from an external power to generate a regulating voltage and a voltage dividing circuit for generate a power supply voltage according to the regulating voltage to supplies power to the electronic device through the power supply voltage, wherein the voltage dividing circuit comprises an impedance regulating apparatus for regulating an impedance of the voltage dividing circuit to vary the power supply voltage according to the variation of the impedance, the method comprising the following steps:
controlling a battery of the electronic device to supplies power to the electronic device and disconnecting a power supply path of supplying the power from the power converter to the electronic device;
allowing the impedance regulating apparatus to regulate the impedance after disconnecting the power supply path to vary the power supply voltage; and
detecting the varied power supply voltage and recognizes the power value according to the varied power supply voltage.

9. The method according to claim 8, further comprising a step of detecting whether the electric quantity of the battery conforms to a default value before the step of controlling the battery of the electronic device to supplies the power to the electronic device and disconnecting the power supply path.

10. The method according to claim 9, wherein if the electric quantity of the battery is larger than the default value, the step of controlling the battery of the electronic device to supplies the power to the electronic device and disconnecting the power supply path is performed, and if the electric quantity of the battery is smaller than the default value, the external power supplies the power to the battery first to make the electric quantity of the battery being larger than the default value and the step of controlling the battery of the electronic device to supplies the power to the electronic device and disconnecting the power supply path is then performed.

11. The method according to claim 8, wherein the voltage dividing circuit comprises a first resistance and a second resistance, the second resistance is connected with the first resistance in series and then grounded, the regulating voltage is inputted between the first resistance and the second resistance, and the impedance regulating apparatus is connected with the second resistance in parallel.

12. The method according to claim 11, wherein the impedance regulating apparatus comprises a third resistance and a switch, the third resistance is connected with the switch in series and then grounded and connected with the second resistance in parallel when the switch is connected or not connected with the second resistance in parallel when the switch is disconnected for varying the impedance of the voltage dividing circuit by connecting or disconnecting the switch.

13. The method according to claim 12, wherein the switch is a relay, a metal-oxide-semiconductor field-effect transistor or a bipolar junction transistor.
